(19) United States
(12) Patent Application Publication
(10) Pub. No.: US 2013/0306712 A1
(43) Pub. Date: Nov. 21, 2013

(54) HOT PRESS DEVICE AND HOT PRESSING METHOD

(71) Applicant: HON HAI PRECISION INDUSTRY CO., LTD., New Taipei (TW)

(72) Inventor: CHIH-CHEN LAI, New Taipei (TW)

(73) Assignee: HON HAI PRECISION INDUSTRY CO., LTD., New Taipei (TW)

(21) Appl. No.: 13/757,863

(22) Filed: Feb. 4, 2013

(30) Foreign Application Priority Data
May 15, 2012 (TW) 101117183

(51) Int. Cl. H05K 13/04

(52) U.S. Cl. CPC H05K 13/0465
USPC 228/180.1; 228/44.7

(57) ABSTRACT

A hot press device includes a spacing strip, a winding roller, a feeding roller and a hot press head. The spacing strip includes a metal layer and a resin layer stacked on the metal layer. The resin layer has a glass transition temperature of greater than 280° C. A contact angle between liquid tin and the metal is smaller than 55 degrees. The ends of the spacing strip are wound around the feeding roller and the winding roller. The hot press head is arranged between the winding roller and the feeding roller. The hot press head has a pressing surface touching the resin layer. A hot pressing method is also related in this disclosure.

### BACKGROUND

1. Technical Field

The present disclosure relates to a hot press device and a hot pressing method using the same for soldering a flexible substrate to a rigid substrate.

2. Description of Related Art

A method for soldering a flexible substrate to a rigid substrate may be that a rigid substrate comprising a number of first electrically conductive pads is provided, and solder paste is deposited on each of the electrically conductive pads. Then, a flexible substrate comprising a number of second electrically conductive pads is provided, and is arranged on the rigid substrate in a manner that the second electrically conductive pads contact the first electrically conductive pads. A hot press head is provided to press a position of the flexible substrate aligned with the first and second electrically conductive pads. The solder paste melts and firmly binds together the first electrically conductive pads and the second electrically conductive pads. Thus, the flexible substrate is firmly connected to the rigid substrate.

In the above method however, the melted solder paste may overflow from the first electrically conductive pads and stain the hot press head. When solder paste accumulates on the hot press head, the hot press head may heat the solder paste between the flexible substrate and the rigid substrate unevenly. This may cause low-quality binding between the first and second electrically conductive pads.

What is needed, therefore, is a hot press device and a hot pressing method using the same to overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic view of a rigid substrate in accordance with an exemplary embodiment.

FIG. 2 is a schematic view of a flexible substrate in accordance with the exemplary embodiment.

FIG. 3 is a schematic view of a hot press device in accordance with the exemplary embodiment.

FIG. 4 is a cross-sectional view of the hot press device of FIG. 3, taken along line IV-IV.

FIG. 5 is similar to FIG. 1, but showing solder paste deposited.

FIG. 6 shows the flexible substrate of FIG. 2 and the rigid substrate of FIG. 5 in contact with each other.

FIG. 7 shows the hot press device of FIG. 3 compressing the flexible substrate and the rigid substrate of FIG. 6.

FIG. 8 is schematic view of a rigid-flexible circuit board comprising the flexible substrate and the rigid substrate of FIG. 7.

### DETAILED DESCRIPTION

Embodiments will be described with reference to the drawings.

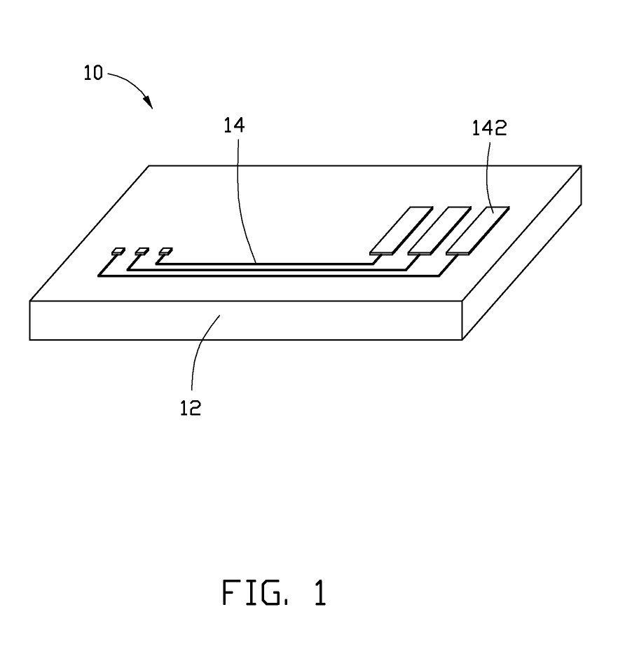

FIGS. 1-8 show a hot pressing method for forming a rigid-flexible circuit board in accordance with a second exemplary embodiment. The method includes the following steps:

Firstly: FIG. 1 shows a rigid substrate 10. The rigid substrate 10 includes a first insulation layer 12, and a first patterned electrically conductive layer 14 arranged on a surface of the first insulation layer 12. The first patterned electrically conductive layer 14 includes a plurality of first electrically conductive pads 142.

In this embodiment, the rigid substrate 10 is a single-sided board. The rigid substrate 10 can also be multilayer board. A material of the first insulation layer 12 can be rigid resin, such as rigid epoxy resin. The rigid substrate 10 can further include a solder mask layer covering part of the first patterned electrically conductive layer 14, and the first electrically conductive pads 142 must then be exposed.

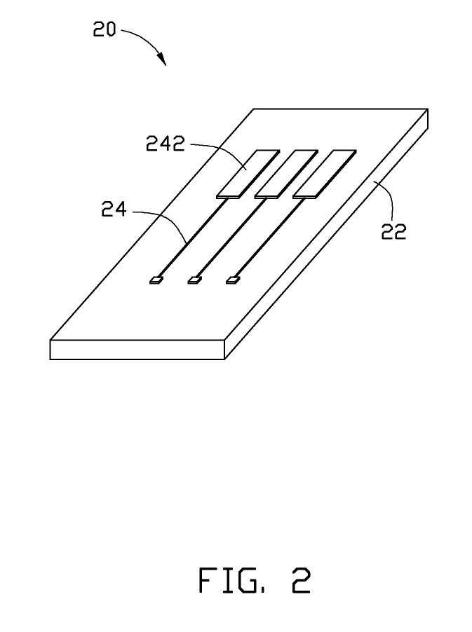

Secondly: FIG. 2 shows a flexible substrate 20. The flexible substrate 20 includes a second insulation layer 22, and a second patterned electrically conductive layer 24 arranged on a surface of the second insulation layer 22. The second patterned electrically conductive layer 24 includes a plurality of second electrically conductive pads 242 corresponding with the first electrically conductive pads 142.

The second insulation layer 22 can be flexible resin, such as polyimide (PI), polyethylene terephtalate (PET), and polythylene naphthalate (PEN). In this embodiment, the flexible substrate 20 is also a single-sided board, but can also be a multilayer board.

The flexible substrate 20 can further include a solder mask layer covering part of the second patterned electrically conductive layer 24, and the second electrically conductive pads 242 must then be exposed.

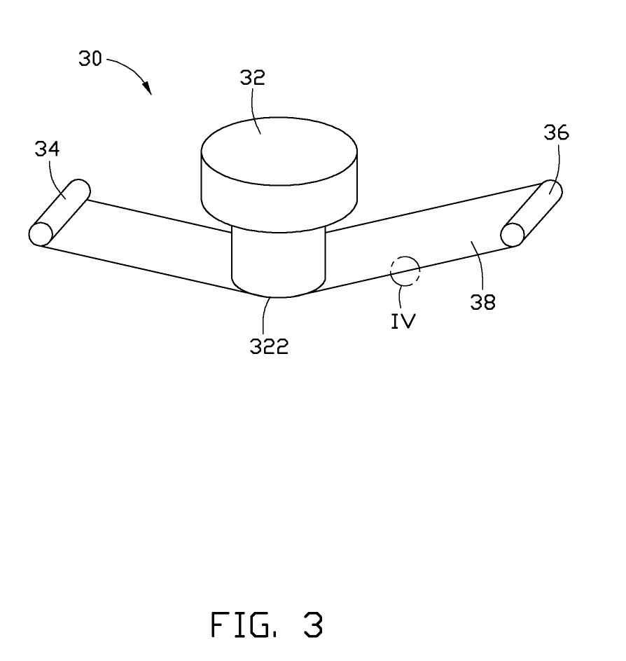

Thirdly: FIG. 3 shows a hot press device 30. The hot press device 30 includes a hot press head 32, a winding roller 34, a feeding roller 36 and a spacing strip 38. The hot press head 32 has a pressing surface 322. The opposite ends of the spacing strip 38 are wound around the feeding roller 36 and the winding roller 34. Part of the spacing strip 38 is arranged between the feeding roller 36 and the winding roller 34. The winding roller 34 is a driving roller, and the feeding roller 36 is a driven roller. A rotation of the winding roller 34 drives the feeding roller 36 to rotate. Thus the spacing strip 38 gradually moves from the feeding roller 36 to the winding roller 34. The hot press head 32 is arranged at an upper side of the spacing strip 38 between the winding roller 34 and the feeding roller 36, and touches the spacing strip 38. The winding roller 34 can be driven to rotate by a motor.

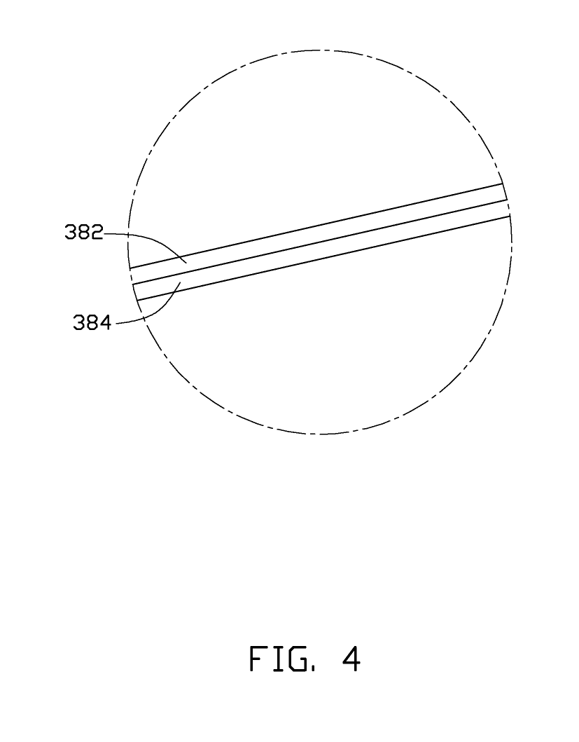

FIG. 4 shows that the spacing strip 38 has a multi-layer structure comprising a metal layer 384 and a resin layer 382 stacked on the metal layer 384. The resin layer 382 is adjacent to the hot press head 32, and touches the pressing surface 322. The resin layer 382 can be polyimide (PI). A glass transition temperature of the resin layer 382 is greater than 280° C. A thickness of the resin layer 382 can be in the range from 20 μm to 100 μm. The solder paste melts to form liquid tin. A contact angle between liquid tin and the metal layer 384 is generally smaller than 55 degrees, and preferably smaller than 45 degrees. A material of the metal layer 384 can be copper or gold.

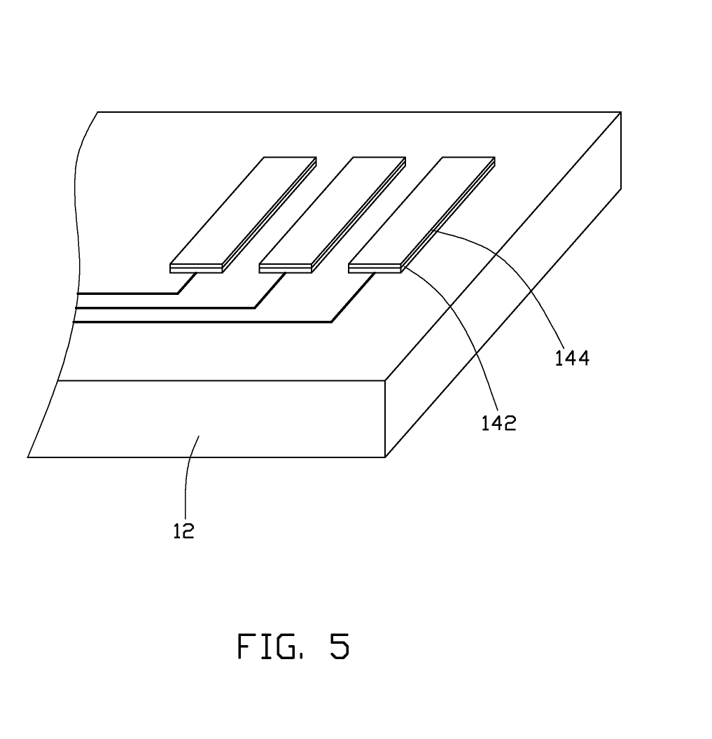

Fourthly: FIG. 5 shows that a solder paste is applied on each of the first electrically conductive pads 142, forming a plurality of solder paste regions 144 corresponding to the first electrically conductive pads 142.

A method for applying the solder paste regions 144 can be a screen printing method described as follows: A printing plate having a plurality of openings corresponding with the first electrically conductive pads 142 is placed on the rigid substrate 10. The openings are aligned with the first electrically conductive pads 142. Then the solder paste is placed on the printing plate, and a filler blade moves across the printing plate, forcing the solder paste to pass through the openings to be deposited on the first electrically conductive pads 142.

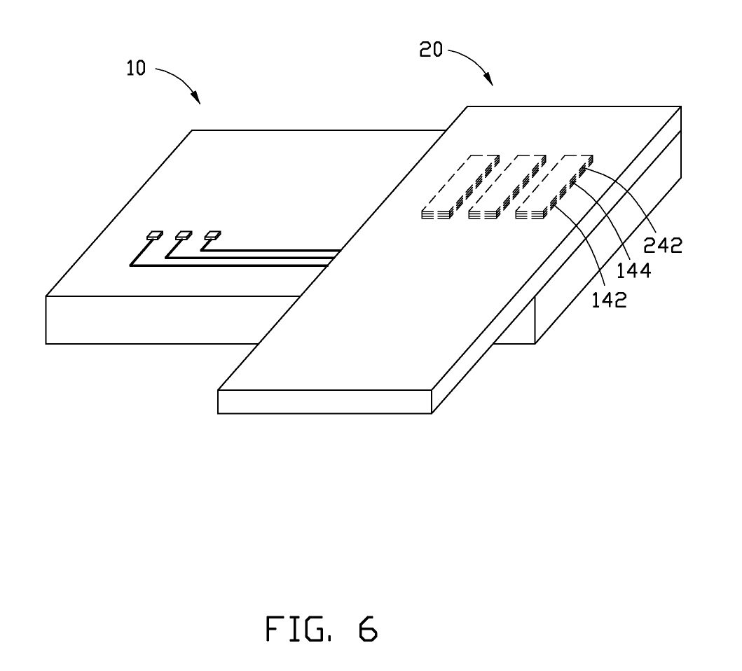

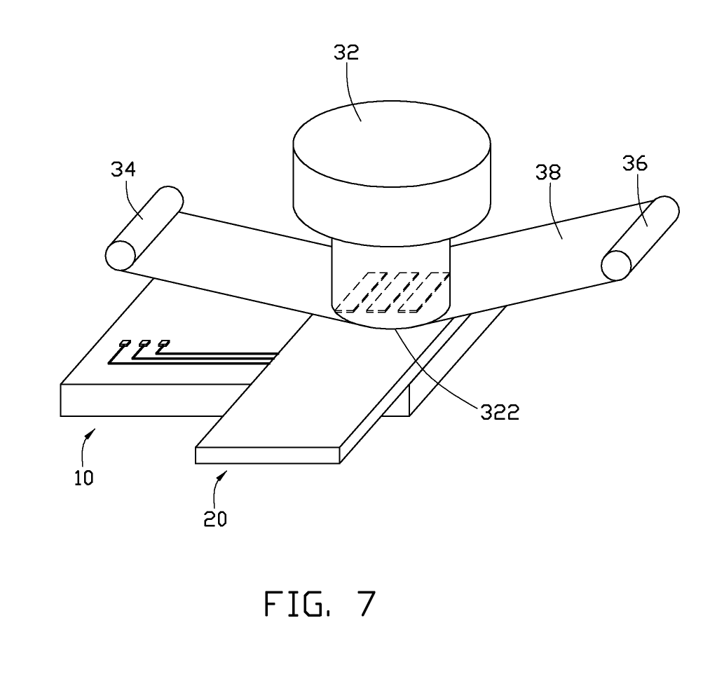

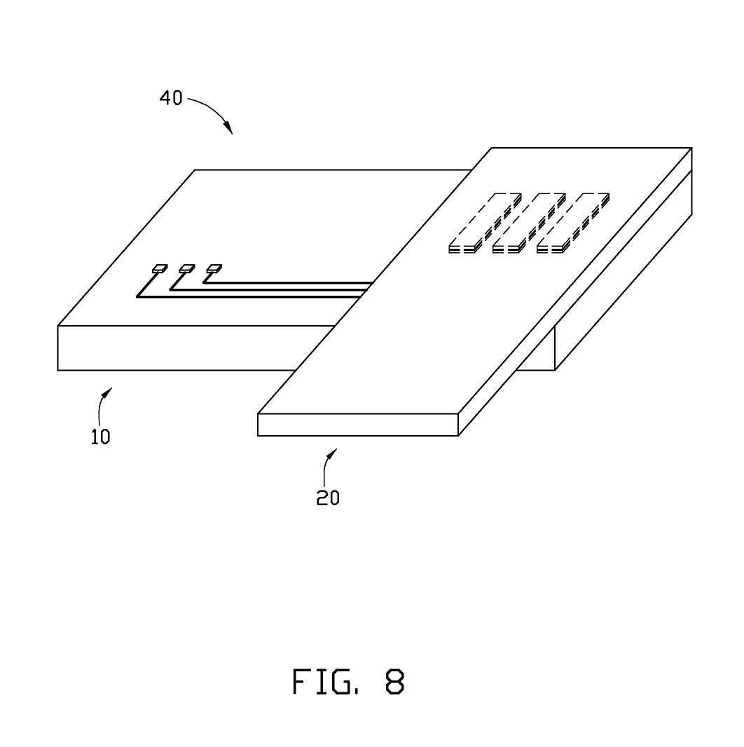

Fifth: FIG. 6 shows that the flexible substrate 20 is placed on the rigid substrate 10 in such a manner that the second electrically conductive pads 242 are respectively aligned with and touch the solder paste regions 144. FIG. 7 shows that the spacing strip 38 touches the flexible substrate 20 which is aligned with the second electrically conductive pads 242. The hot press head 32 presses together the spacing strip 38, the flexible substrate 20 and rigid substrate 10, and heats the solder paste regions 144. The solder paste of solder paste regions 144 is melted to bind and electrically connect the first electrically conductive pads 142 and the second electrically conductive pads 242, due to the heating of the hot press head 32. FIG. 8 shows that a rigid-flexible circuit board 40 is obtained after the melted solder paste is cooled.

In this embodiment, a temperature of the hot press head 32 is about 280° C. and the heat is transferred through flexible substrate 20 to the solder paste regions 144. If any melted solder paste overflows from the first electrically conductive pads 142, the overflow will flow onto the spacing strip 38, thereby avoiding stains and contamination on the hot press head 32.

Sixth: The winding roller 34 is driven to rotate, causing part of the spacing strip 38 to move on from the hot press head 32, and another part of the spacing strip 38 to move to a position under the hot press head 32.

The first, second, fourth, fifth, and sixth steps are repeated until a predetermined number of rigid-flexible circuit boards 40 are obtained.

In this embodiment, the used part of the spacing strip 38 moves away from the hot press head 32, and an unused part of the spacing strip 38 moves to a position under the hot press head 32, ensuring that there is no overflow of solder paste under the hot press head 32 whenever the hot press head 32 presses the flexible substrate 20.

While certain embodiments have been described and exemplified above, various other embodiments will be apparent to those skilled in the art from the foregoing disclosure. The present disclosure is not limited to the particular embodiments described and exemplified but is capable of considerable variation and modification without departure from the scope of the appended claims.

What is claimed is:

1. A hot press device for soldering a flexible substrate to a rigid substrate, the flexible substrate being placed on the rigid substrate, comprising:
a spacing strip comprising a metal layer and a resin layer stacked on the metal layer, the resin layer having a glass transition temperature of greater than 280° C., a contact angle between liquid tin and the metal layer being smaller than 55 degrees;
a winding roller and a feeding roller, two opposite ends of the spacing strip being respectively wound around the feeding roller and the winding roller, part of the spacing strip being arranged between the feeding roller and the winding roller; and
a hot press head, the hot press head arranged between the winding roller and the feeding roller, the part of the spacing strip configured for being sandwiched between the hot press head and the flexible substrate, the hot press head having a pressing surface touching the resin layer of the part of the spacing strip, the hot press head being configured for heating and pressing the flexible substrate and the rigid substrate to melt solder paste arranged between the flexible substrate and the rigid substrate, thereby soldering the flexible substrate to the rigid substrate, the winding roller and the feeding roller configured to rotate to move the part of the spacing strip during the flexible substrate and the rigid substrate are heated and pressed by the hot press head.

2. The hot press device of claim 1, wherein a material of the resin layer is polyimide.

3. The hot press device of claim 1, wherein a thickness of the resin layer is in the range from 20 μm to 100 μm.

4. The hot press device of claim 1, wherein the contact angle is smaller than 45°.

5. The hot press device of claim 4, wherein a material of the metal layer is copper or gold.

6. A hot pressing method, comprising:
S1: proving a rigid substrate comprising a first rigid insulation layer and a first patterned electrically conductive layer arranged on the first patterned electrically conductive layer, the first patterned electrically conductive layer comprising a plurality of first electrically conductive pads;
S2: providing a flexible substrate comprising a second insulation layer and a second electrically conductive layer arranged on the second insulation layer, the second electrically conductive layer comprising a plurality of second electrically conductive pads corresponding to the first electrically conductive pads;
S3: applying a solder paste onto each of the first electrically conductive pads to form a plurality of solder paste regions;
S4: placing the flexible substrate on the rigid substrate in a manner that the second electrically conductive pads are respectively aligned with and touch the solder paste regions;
S5: providing the hot press device of claim 1, and heating and pressing the flexible substrate and the rigid substrate with the pressing surface being aligned with the second electrically conductive pads, part of the spacing strip between the winding roller and the feeding roller being arranged between the hot press head and the flexible substrate, the metal layer touching the flexible substrate, the solder paste being melted by heating of the hot press head, and soldering the first electrically conductive pads to the second electrically conductive pads, thereby obtaining a rigid-flexible circuit board;
S6: rotating the winding roller to cause a portion of the spacing strip pressed by the hot press head to leave the hot press head, and neighboring part of the spacing strip to move to a position under the hot press head.

7. The method of claim 6, wherein a temperature for heating the flexible substrate and the rigid substrate is about 280° C.

8. The method of claim 6, wherein the step of applying the solder paste onto each of the first electrically conductive pads comprises: placing a printing plate having a plurality of openings corresponding to the first electrically conductive pads on the rigid substrate, the openings are respectively aligned with the first electrically conductive pads; placing the solder paste on the printing plate; and using a fill blade to move across the printing plate, forcing the solder paste to pass through the openings to deposit onto the electrically conductive pads.

9. The method of claim 6, wherein a material of the first insulation layer is rigid epoxy, and a material of the second insulation layer is selected from the group consisting of polyimide, polyethylene terephtalate, and polythylene naphthalate.
